(19) United States
(12) Patent Application Publication
(10) Pub. No.: US 2017/0200803 A1
(43) Pub. Date: Jul. 13, 2017

(54) SEMICONDUCTOR DEVICE AND METHOD FOR FABRICATING THE SAME

(71) Applicant: SAMSUNG ELECTRONICS CO., LTD., Suwon-si (KR)

(72) Inventor: HYUNG-SUK LEE, SUWON-SI (KR)

(21) Appl. No.: 14/992,080

(22) Filed: Jan. 11, 2016

(51) Int. Cl. H01L 29/51; H01L 29/06; H01L 27/088; H01L 29/78

(52) U.S. Cl. CPC H01L 29/511; H01L 29/785; H01L 29/0649; H01L 27/0886

(57) ABSTRACT

A semiconductor device is provided. The Semiconductor device includes a first active fin and a second active fin disposed on a substrate. A first gate electrode intersects the first active fin. A second gate electrode intersects the second active fin. A first gate insulation layer includes a first high dielectric constant insulation layer. The first gate insulation layer is disposed between the first gate electrode and the first active fin. A second gate insulation layer includes a second high dielectric constant insulation layer. The second gate insulation layer is disposed between the second gate electrode and the second active fin. A thickness of the first high dielectric constant insulation layer is thicker than a thickness of the second high dielectric constant insulation layer.

### TECHNICAL FIELD

Exemplary embodiments of the present inventive concept relate to a semiconductor device, and more particularly to a method for fabricating the same.

### DISCUSSION OF RELATED ART

Semiconductor devices may be relatively small and may have relatively high performance. Thus, slight structural differences of transistors contained in semiconductor devices may influence performance of the semiconductor devices.

In general, a gate insulation layer may include silicon oxide. Semiconductor devices may include a gate insulation layer having reduced thickness.

### SUMMARY

Exemplary embodiments of the present inventive may provide a semiconductor device in which a thickness of a gate insulation layer is adjusted to increase reliability.

According to an exemplary embodiment of the present inventive concept, a semiconductor device includes a first active fin and a second active fin disposed on a substrate. A first gate electrode intersects the first active fin. A second gate electrode intersects the second active fin. A first gate insulation layer includes a first high dielectric constant insulation layer. The first gate insulation layer is disposed between the first gate electrode and the first active fin. A second gate insulation layer includes a second high dielectric constant insulation layer. The second gate insulation layer is disposed between the second gate electrode and the second active fin. A thickness of the first high dielectric constant insulation layer is thicker than a thickness of the second high dielectric constant insulation layer.

In some exemplary embodiments of the present inventive concept, the first high dielectric constant insulation layer may include a first lower high dielectric constant insulation layer and a first upper high dielectric constant insulation layer sequentially disposed on the first active fin.

In some exemplary embodiments of the present inventive concept, the second high dielectric constant insulation layer may include a same material as a material included in the upper high dielectric constant insulation layer.

In some exemplary embodiments of the present inventive concept, the first gate insulation layer may include a first interfacial insulation layer between the first active fin and the first high dielectric constant insulation layer. The second gate insulation layer may include a second interfacial insulation layer between the second active fin and the second high dielectric constant insulation layer.

In some exemplary embodiments of the present inventive concept, a thickness of the first interfacial insulation layer and a thickness of the second interfacial insulation layer may be different from each other.

In some exemplary embodiments of the present inventive concept, a dielectric constant of the first high dielectric constant insulation layer may be higher than a dielectric constant of the first interfacial insulation layer. A dielectric constant of the second high dielectric constant insulation layer may be higher than a dielectric constant of the second interfacial insulation layer.

In some exemplary embodiments of the present inventive concept, the first high dielectric constant insulation layer may be disposed on a bottom surface of the first gate electrode and a sidewall of the first gate electrode. The second high dielectric constant insulation layer may be disposed on a bottom surface of the second gate electrode and a sidewall of the second gate electrode.

In some exemplary embodiments of the present inventive concept, the thickness of the first high dielectric constant insulation layer between a bottom surface of the first gate electrode and an upper surface of the first active fin may be thicker than the thickness of the second high dielectric constant insulation layer between a bottom surface of the second gate electrode and an upper surface of the second active fin.

In some exemplary embodiments of the present inventive concept, a width of the first gate electrode may be different from a width of the second gate electrode.

According to an exemplary embodiment of the present inventive concept, a semiconductor device includes a first active fin and a second active fin disposed on a substrate. A first gate electrode intersects the first active fin. A first gate spacer is disposed on a sidewall of the first gate electrode. The first gate spacer defines a first trench. A first gate insulation layer includes a first high dielectric constant insulation layer between the first gate electrode and the first active fin. The first gate insulation layer is disposed on a sidewall and a bottom surface of the first trench. The first high dielectric constant insulation layer includes a first lower high dielectric constant insulation layer and a first upper high dielectric constant insulation layer. A second gate electrode intersects the second active fin. A second gate spacer is disposed on a sidewall of the second gate electrode. The second gate spacer defines a second trench having a width narrower than a width of the first trench. A second gate insulation layer includes a second high dielectric constant insulation layer between the second gate electrode and the second active fin. The second gate insulation layer is disposed along a sidewall and a bottom surface of the second trench.

In some exemplary embodiments of the present inventive concept, a thickness of the first high dielectric constant insulation layer and a thickness of the second high dielectric constant insulation layer may be different from each other.

In some exemplary embodiments of the present inventive concept, the thickness of the first high dielectric constant insulation layer between a bottom surface of the first gate electrode and an upper surface of the first active fin may be thicker than the thickness of the second high dielectric constant insulation layer between a bottom surface of the second gate electrode and an upper surface of the second active fin.

In some exemplary embodiments of the present inventive concept, the first gate insulation layer may include a first interfacial insulation layer between the first active fin and the first high dielectric constant insulation layer. The second gate insulation layer may include a second interfacial insulation layer between the second active fin and the second high dielectric constant insulation layer.

In some exemplary embodiments of the present inventive concept, a dielectric constant of the first high dielectric constant insulation layer may be higher than a dielectric constant of the first interfacial insulation layer. A dielectric constant of the second high dielectric constant insulation layer may be higher than a dielectric constant of the second interfacial insulation layer.

In some exemplary embodiments of the present inventive concept, the first interfacial insulation layer and the second interfacial insulation layer may include silicon oxide.

### BRIEF DESCRIPTION OF THE DRAWINGS

The above and other features of the present inventive concept will become more apparent by describing in detail preferred embodiments thereof with reference to the attached drawings in which:

FIG. 1 is a perspective view of a semiconductor device according to some exemplary embodiments of the present inventive concept;

FIG. 2a is a cross-sectional view taken along lines A-A and C-C of FIG. 1;

FIG. 2b is an enlarged view of I plane and J plane of FIG. 2a;

FIG. 3 is a cross-sectional view taken along lines B-B and D-D of FIG. 1;

FIG. 4 is a perspective view of a semiconductor device according to some exemplary embodiments of the present inventive concept;

FIG. 5a is a cross-sectional view taken along lines E-E and G-G of FIG. 4;

FIG. 5b is an enlarged view of K plane and L plane of FIG. 5a;

FIG. 6 is a cross-sectional view taken along lines F-F and H-H of FIG. 4;

FIG. 7 is a perspective view of a semiconductor device according to some exemplary embodiments of the present inventive concept;

FIG. 8 is a cross-sectional view taken along lines M-M and N-N of FIG. 7;

FIG. 9 is a cross-sectional view taken along lines O-O and P-P of FIG. 7;

FIG. 10 to FIG. 26 are diagrams illustrating intermediate process steps of a method for fabricating a semiconductor device according to some exemplary embodiments of the present inventive concept; and

FIG. 27 is a block diagram of a system-on-chip (SoC) system including a semiconductor device according to some exemplary embodiments of the present inventive concept.

### DETAILED DESCRIPTION OF THE EMBODIMENTS

Exemplary embodiments of the present inventive concept will be described in more detail below with reference to the accompanying drawings, in which exemplary embodiments of the present inventive concept are shown. Exemplary embodiments of the present inventive concept may, however, be embodied in different forms and should not be construed as limited to the embodiments set forth herein. The same reference numbers may indicate the same components throughout the specification and drawings. In the attached figures, the thickness of layers and regions may be exaggerated for clarity.

It will be understood that when an element or layer is referred to as being “connected to,” or “coupled to” another element or layer, it may be directly connected to or coupled to another element or layer or intervening elements or layers may be present.

When a layer is referred to as being “on” another layer or substrate, it may be directly on the other layer or substrate, or intervening layers may also be present.

It will be understood that, although the terms first and second may be used herein to describe various elements, these elements should not be limited by these terms.

Although the description below may describe a semiconductor device using a FINFET including a fin type pattern, it will become apparent that the semiconductor device may be a planar transistor formed on a substrate.

It will become apparent that the semiconductor device according to some exemplary embodiments of the present inventive concept may be a transistor including a nano wire.

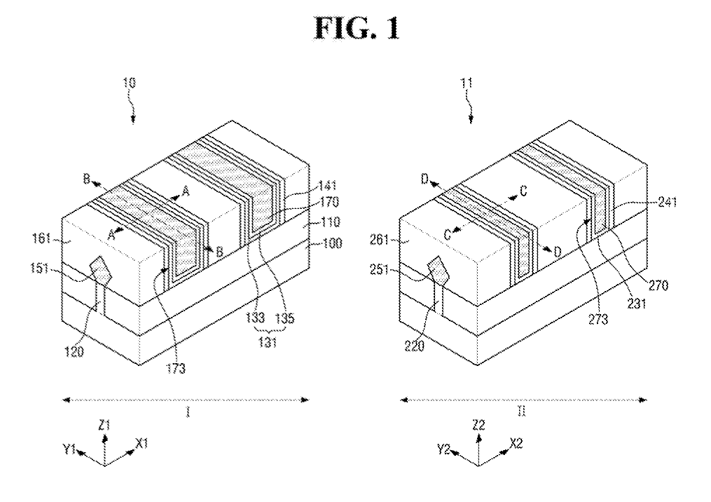

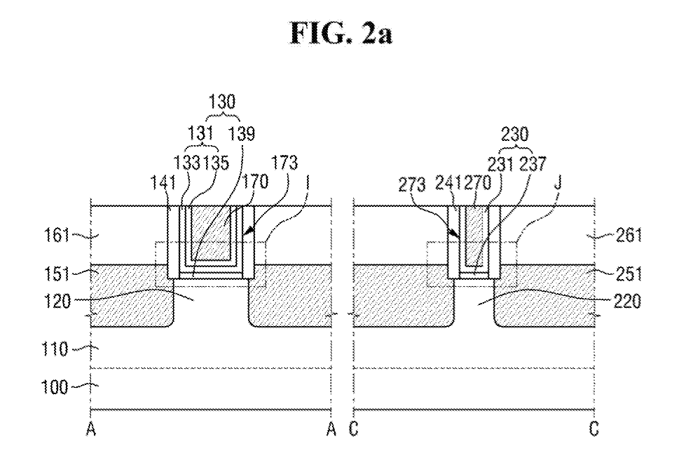

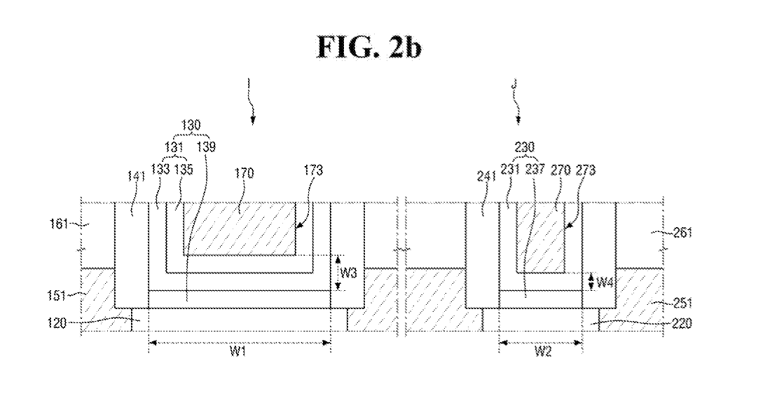

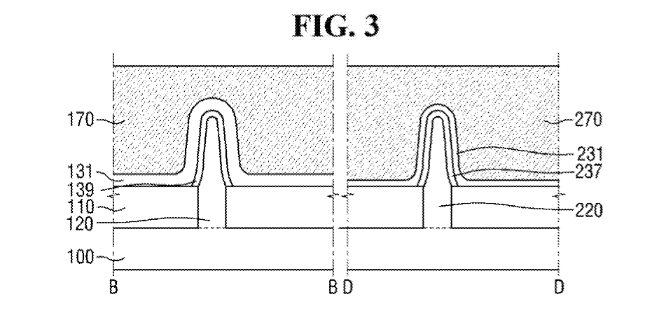

The semiconductor device according to some exemplary embodiments of the present inventive concept will now be described in more detail with reference to FIG. 1, FIG. 2a, FIG. 2b and FIG. 3.

FIG. 1 is a perspective view of a semiconductor device according to some exemplary embodiments of the present inventive concept. FIG. 2a is a cross-sectional view taken along lines A-A and C-C of FIG. 1. FIG. 2b is an enlarged view of I plane and J plane of FIG. 2a. FIG. 3 is a cross-sectional view taken along lines B-B and D-D of FIG. 1.

Referring to FIG. 1, FIG. 2a, FIG. 2b and FIG. 3, the semiconductor device according to some exemplary embodiments of the present inventive concept may include a first transistor 10 and a second transistor 11.

A substrate 100 may include a first region I and a second region II. The first region I and the second region II may be adjacent to or spaced apart from each other.

The substrate 100 may be, for example, bulk silicon or silicon-on-insulator (SOI). The substrate 100 may be a silicon substrate. The substrate 100 may include materials other than silicon, for example, silicon germanium, indium antimonide, lead telluride, indium arsenide, indium phosphide, gallium arsenide or gallium antimonide. The substrate 100 may be a substrate in which an epitaxial layer is formed on a base substrate.

The first transistor 10 may be formed in the first region I and the second transistor 11 may be formed in the second region II.

The first transistor 10 and the second transistor 11 may respectively include a first active fin 120 and a second active fin 220 protruding from the substrate 100.

A field insulation layer 110 formed on the substrate 100 may cover a part of the first active fin 120 and a part of the second active fin 220.

At least a part of the first active fin 120 and at least a part of the second active fin 220 may protrude further than an upper surface of the field insulation layer 110.

Although sidewalls of the first active fin 120 and the second active fin 220 are depicted as having a vertical slope with respect to the substrate 100, exemplary embodiments of the present inventive concept are not limited thereto.

The sidewalls of the first active fin 120 and the second active fin 220 may have a slope, and for example, the first active fin 120 and the second active fin 220 may have a tapered shape. The first active fin 120 and the second active fin 220 may have a chamfered shape. The first active fin 120 and the second active fin 220 may have rounded corners.

The first active fin 120 and the second active fin 220 may each be a part of the substrate 100. The first active fin 120 and the second active fin 220 may each include an epitaxial layer which is formed using the substrate 100 as a seed layer.

The first active fin 120 and the second active fin 220 may each include, for example, silicon or germanium. The first active fin 120 and the second active fin 220 may each include compound semiconductors, for example, group IV-IV compound semiconductors or group III-V compound semiconductors. As an example of IV-IV compound semiconductors, each of the first active fin 120 and the second active fin 220 may include a binary compound or a ternary compound including at least two of carbon (C), silicon (Si), germanium (Ge) and tin (Sn), or a compound prepared by doping a group IV element thereto. As an example of group III-V compound semiconductors, each of the first active fin 120 and the second active fin 220 may include one of a binary compound, a ternary compound and a quaternary compound prepared by bonding at least one of aluminum (Al), gallium (Ga) and indium (In) as a group III element and one of phosphorus (P), arsenic (As) and antimonium (Sb) as a group V element.

The field insulation layer 110 may include a material including, for example, at least one of a silicon oxide layer, a silicon nitride layer and a silicon oxynitride layer.

The first transistor 10 may include a first gate electrode 170 intersecting the first active fin 120. The second transistor 11 may include a second gate electrode 270 intersecting the second active fin 220.

Although each of the first gate electrode 170 and the second gate electrode 270 is depicted in FIG. 1 to FIG. 3 as having a single layer structure, exemplary embodiments of the present inventive concept are not limited thereto.

For example, each of the first gate electrode 170 and the second gate electrode 270 may be formed by stacking two or more metal layers, respectively. The first gate electrode 170 and the second gate electrode 270 may include a work function regulating metal layer, and a metal layer filling a space formed by the work function regulating metal layer.

The first gate electrode 170 may have a width different from the width of the second gate electrode 270.

The width of the first gate electrode 170 may be wider than the width of the second gate electrode 270.

Each of the first gate electrode 170 and the second gate electrode 270 may include, for example, a conductive material. Examples of the conductive material may include doped polysilicon, titanium nitride (TiN), tantalum nitride (TaN), tungsten nitride (WN), titanium (Ti), tantalum (Ta), and tungsten (W), however, exemplary embodiments of the present inventive concept are not limited thereto.

The first transistor 10 may include a first gate spacer 141. The first gate spacer 141 may be formed on a sidewall of the first gate electrode 170. The first gate spacer 141 may define a first trench 173.

The second transistor 11 may include a second gate spacer 241. The second gate spacer 241 may be formed on a sidewall of the second gate electrode 270. The second gate spacer 241 may define a second trench 273.

The first trench 173 may be defined by the first gate spacer 141. The first gate spacer 141 may define a sidewall of the first trench 173, and an upper surface of the first active fin 120 may define a bottom surface of the first trench 173.

The second trench 273 may be defined by the second gate spacer 241. The second gate spacer 241 may define a sidewall of the second trench 273, and an upper surface of the second active fin 220 may define a bottom surface of the second trench 273.

The first trench 173 may have a width W1 different from a width W2 of the second trench 273.

The width W2 of the second trench 273 may be narrower than the width W1 of the first trench.

Although the first gate spacer 141 and the second gate spacer 241 are depicted in

FIG. 1 to FIG. 3 as having a single layer structure, exemplary embodiments of the present inventive concept are not limited thereto.

The first gate spacer 141 and the second gate spacer 241 may have a multi-layer structure.

The first gate spacer 141 and the second gate spacer 241 may include, for example, one of silicon nitride (SiN), silicon oxynitride (SiON), silicon oxide (SiO₂), silicon carbon oxynitride (SiOCN) and a combination thereof.

The first transistor 10 may include a first semiconductor pattern 151, and the second transistor 11 may include a second semiconductor pattern 251.

The first semiconductor pattern 151 and the second semiconductor pattern 251 may be disposed, respectively, on upper surfaces of the first active fin 120 and the second active fin 220 and sidewalls of the first gate electrode 170 and the second gate electrode 270.

The first semiconductor pattern 151 and the second semiconductor pattern 251 may have at least one of a diamond shape, a circular shape and a rectangular shape. Although the first semiconductor pattern 151 and the second semiconductor pattern 251 are depicted in FIG. 1 as having a diamond shape, exemplary embodiments of the present inventive concept are not limited thereto. For example, the first semiconductor pattern 151 and the second semiconductor pattern 251 may each have a pentagonal shape or a hexagonal shape.

Each of the first semiconductor pattern 151 and the second semiconductor pattern 251 may be a source/drain of the first transistor 10 and the second transistor 11 respectively, and for example, an elevated source/drain.

The first semiconductor pattern 151 and the second semiconductor pattern 251 may be formed respectively on the first active fin 120 and the second active fin 220 by an epitaxial growth process.

When the first transistor 10 formed using the first active fin 120 or the second transistor 11 formed using the second active fin 220 is a PMOS transistor, the first semiconductor pattern 151 or the second semiconductor pattern 251 may include compressive stress materials. For example, the compressive stress materials may have a lattice constant larger than that of Si, and may be, for example, SiGe. The compressive stress materials may apply compressive stress to each of the first active fin 120 or the second active fin 220 and may increase carrier mobility in a channel region.

When the first transistor 10 formed using the first active fin 120 or the second transistor 11 formed using the second active fin 220 is an NMOS transistor, the first semiconductor pattern 151 or the second semiconductor pattern 251 may include materials that are the same as those of the substrate 100. The first semiconductor pattern 151 or the second semiconductor pattern 251 may each include tensile stress materials. For example, when the substrate 100 is made of Si, the first semiconductor pattern 151 or the second semiconductor pattern 251 may include Si or materials having a lattice constant smaller than that of Si (for example, SiC).

A first inter layer dielectric 161 and a second inter layer dielectric 261 may be formed on the field insulation layer 110. The first inter layer dielectric 161 may cover the first semiconductor pattern 151, and the second inter layer dielectric 261 may cover the second semiconductor pattern 251.

The first inter layer dielectric 161 and the second inter layer dielectric 261 may each include, for example, at least one of a low dielectric constant material, an oxide layer, a nitride layer and an oxynitride layer. The low dielectric constant material may include, for example, flowable oxide (FOX), torene silazene (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP), plasma enhanced oxide (PEOX), flowable CVD (FCVD) or a combination thereof, but exemplary embodiments of the present inventive concept are not limited thereto.

The first transistor 10 may include a first gate insulation layer 130 disposed between the first gate electrode 170 and the first active fin 120.

The first gate insulation layer 130 may be formed along the sidewall and the bottom surface of the first trench 173.

The first gate insulation layer 130 may include a first high dielectric constant insulation layer 131.

The first high dielectric constant insulation layer 131 may be formed on a bottom surface and the sidewall of the first gate electrode 170.

The first high dielectric constant insulation layer 131 may include a first lower high dielectric constant insulation layer 133 and a first upper high dielectric constant insulation layer 135 which are sequentially stacked.

The first lower high dielectric constant insulation layer 133 and the first upper high dielectric constant insulation layer 135 may be sequentially stacked on the bottom surface and the sidewall of the first gate electrode 170.

In some exemplary embodiments of the present inventive concept, the first gate insulation layer 130 may include a first interfacial insulation layer 139 disposed between the first active fin 120 and the first high dielectric constant insulation layer 131.

The first interfacial insulation layer 139 may be formed on the first active fin 120 and may be disposed higher than an upper surface of the field insulation layer 110. The first interfacial insulation layer 139 need not extend along the upper surface of the field insulation layer 110.

The second transistor 11 may include a second gate insulation layer 230 disposed between the second gate electrode 270 and the second active fin 220.

The second gate insulation layer 230 may be formed along a sidewall and bottom surface of the second trench 273.

The second gate insulation layer 230 may include a second high dielectric constant insulation layer 231.

The second high dielectric constant insulation layer 231 may be formed on a bottom surface and sidewall of the second gate electrode 270.

In some exemplary embodiments of the present inventive concept, the second gate insulation layer 230 may include a second interfacial insulation layer 237 disposed between the second active fin 220 and the second high dielectric constant insulation layer 231

The second interfacial insulation layer 237 may be formed on the second active fin 220 and may be disposed higher than the upper surface of the field insulation layer 110. The second interfacial insulation layer 237 need not extend along the upper surface of the field insulation layer 110.

Each of the first interfacial insulation layer 139 and the second interfacial insulation layer 237 may extend along the upper surface of the field insulation layer 110 according to a method for forming the first interfacial insulation layer 139 and the second interfacial insulation layer 237.

The first high dielectric constant insulation layer 131 may have a thickness W3 different from a thickness W4 of the second high dielectric constant insulation layer 231.

For example, the thickness W3 of the first high dielectric constant insulation layer 131 may be thicker than the thickness W4 of the second high dielectric constant insulation layer 231.

The thickness W3 of the first high dielectric constant insulation layer 131 may be a distance between the bottom surface of the first gate electrode 170 and an upper surface of the first active fin 120.

The thickness W4 of the second high dielectric constant insulation layer 231 may be a distance between the bottom surface of the second gate electrode 270 and the upper surface of the second active fin 220.

The second high dielectric constant insulation layer 231 and the first upper high dielectric constant insulation layer 135 may be formed at the same level. The term “same level” as used herein may mean being formed by the same manufacturing process.

The second high dielectric constant insulation layer 231 may include a same material as that of the first upper high dielectric constant insulation layer 135.

Each of the first lower high dielectric constant insulation layer 133 and the first upper high dielectric constant insulation layer 135 may include a high dielectric constant material. The high dielectric constant material may have dielectric constant higher than that of a silicon oxide layer.

Each of the first lower high dielectric constant insulation layer 133 and the first upper high dielectric constant insulation layer 135 may include one or more among hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, but exemplary embodiments of the present inventive concept are not limited thereto.

For example, the first lower high dielectric constant insulation layer 133 may include a material having an etch selectivity with respect to a material of the first gate spacer 141.

Each of the first interfacial insulation layer 139 and the second interfacial insulation layer 237 may include, for example, silicon oxide, but exemplary embodiments of the present inventive concept are not limited thereto.

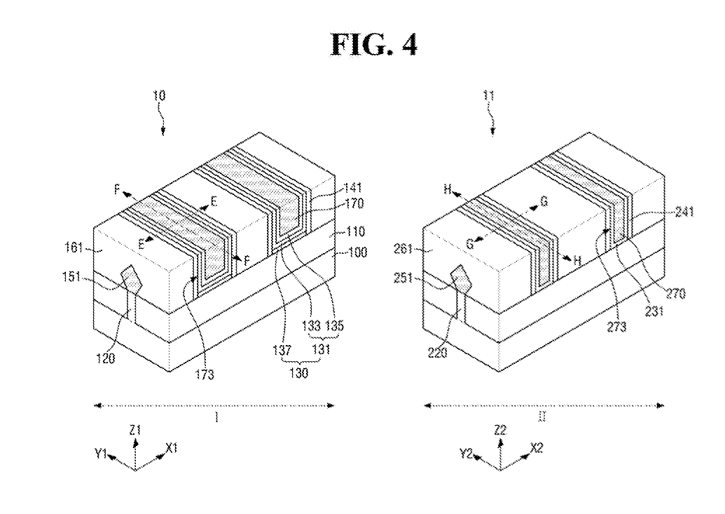

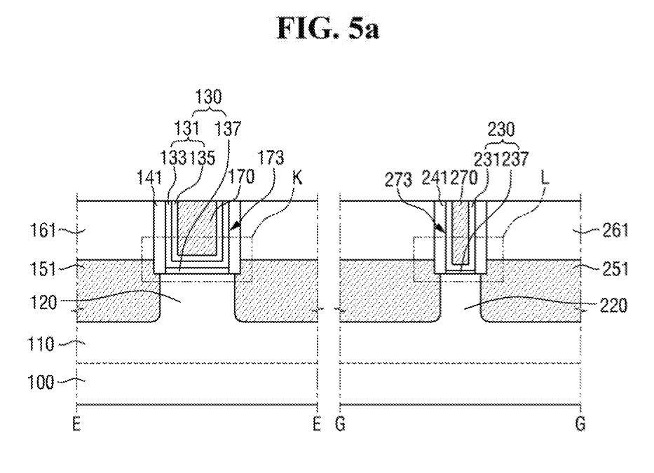

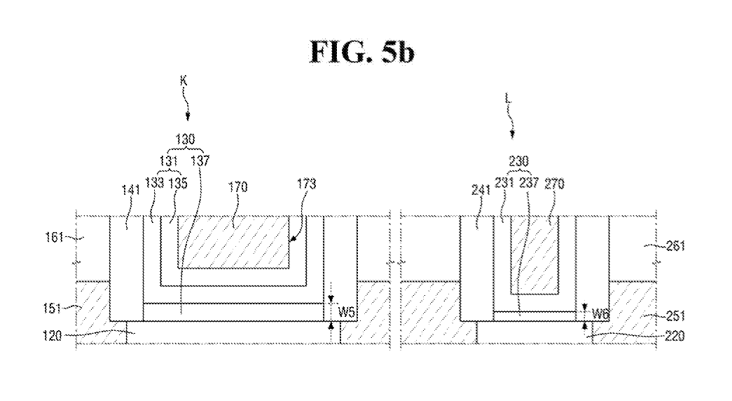

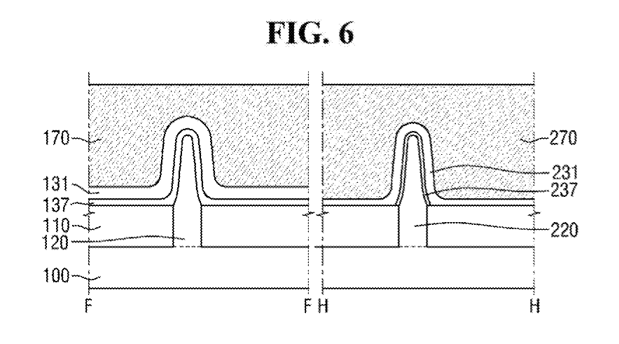

FIG. 4 is a perspective view of a semiconductor device according to some exemplary embodiments of the present inventive concept. FIG. 5a is a cross-sectional view taken along lines E-E and G-G of FIG. 4. FIG. 5b is an enlarged view of K plane and L plane of FIG. 5a. FIG. 6 is a cross-sectional view taken along lines F-F and H-H of FIG. 4.

FIG. 4, FIG. 5a, FIG. 5b and FIG. 6 illustrate a semiconductor device according to some exemplary embodiments of the present inventive concept. Duplicate descriptions of the same content as those of the foregoing exemplary embodiments may be omitted.

Referring to FIG. 4, FIG. 5a, FIG. 5b and FIG. 6, in the semiconductor device according to some exemplary embodiments of the present inventive concept, the first gate insulation layer 130 may include an interfacial layer 137 disposed between the first active fin 120 and the first high dielectric constant insulation layer 131.

The interfacial layer 137 may extend in a Y1 direction on the first active fin 120 and the field insulation layer 110.

The interfacial layer 137 may be formed on the field insulation layer 110 and on the first active fin 120.

The interfacial layer 137 may have a thickness W5 different from a thickness W6 of the second interfacial insulation layer 237.

The thickness W5 of the interfacial layer 137 may be thicker than the thickness W6 of the second interfacial insulation layer 237.

The interfacial layer 137 may include, for example, silicon oxide.

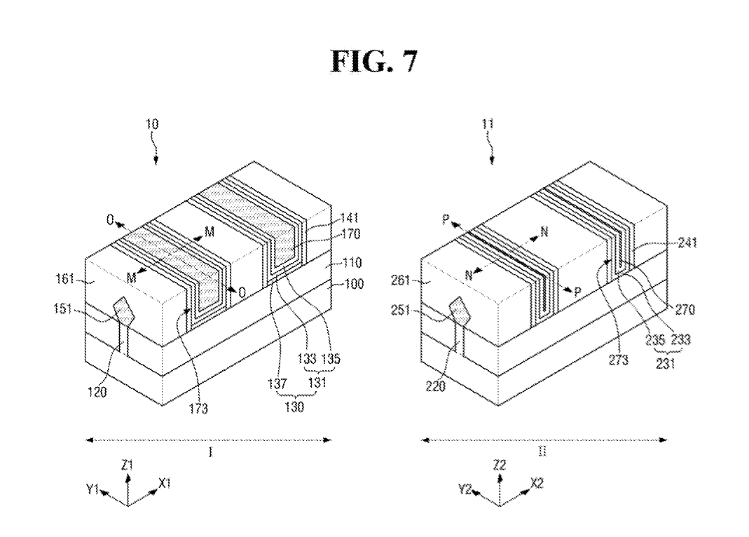

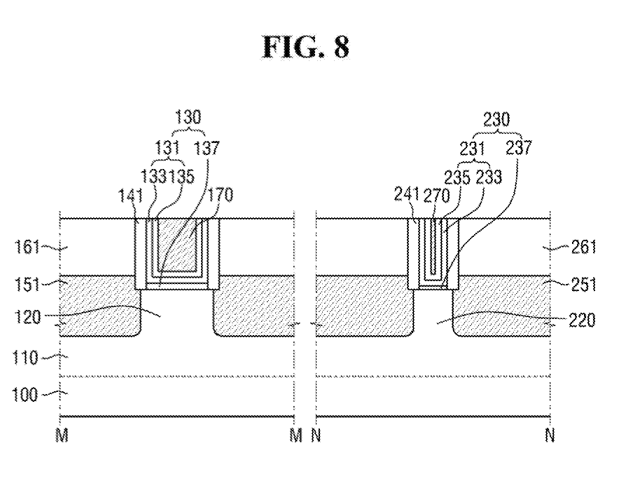

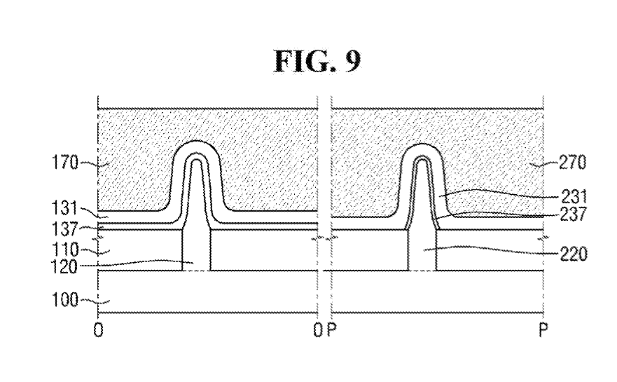

FIG. 7 is a perspective view of a semiconductor device according to some exemplary embodiments of the present inventive concept. FIG. 8 is a cross-sectional view taken along lines M-M and N-N of FIG. 7. FIG. 9 is a cross-sectional view taken along lines O-O and P-P of FIG. 7.

FIG. 7 to FIG. 9 illustrate a semiconductor device according to some exemplary embodiments of the present inventive concept. Duplicate descriptions of the same content as those of the foregoing exemplary embodiments may be omitted.

Referring to FIG. 7 to FIG. 9, in the semiconductor device according to some exemplary embodiments of the present inventive concept, the second high dielectric constant insulation layer 231 may include the second lower high dielectric constant insulation layer 233 and the second upper high dielectric constant insulation layer 235.

The second lower high dielectric constant insulation layer 233 and the second upper high dielectric constant insulation layer 235 may be sequentially stacked along the sidewall and the bottom surface of the second trench 273 on the second fin 220.

The second lower high dielectric constant insulation layer 233 may include a same material as that of the first lower high dielectric constant insulation layer 133.

The second upper high dielectric constant insulation layer 235 may include a same material as that of the first upper high dielectric constant insulation layer 135.

The semiconductor device according to some exemplary embodiments of the present inventive concept may include the first high dielectric constant insulation layer 131. The first high dielectric constant layer 131 may include two layers and thus the thickness of the first interfacial insulation layer 139 may be relatively thin, thus increasing reliability of the semiconductor device.

The first interfacial insulation layer 139 may be relatively thin and may reduce or prevent a pinch-off phenomenon between active fins.

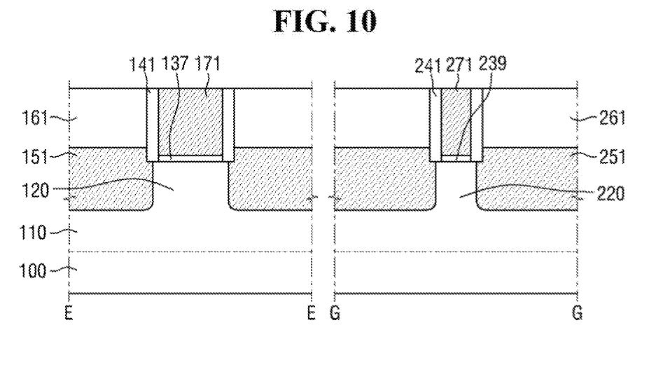

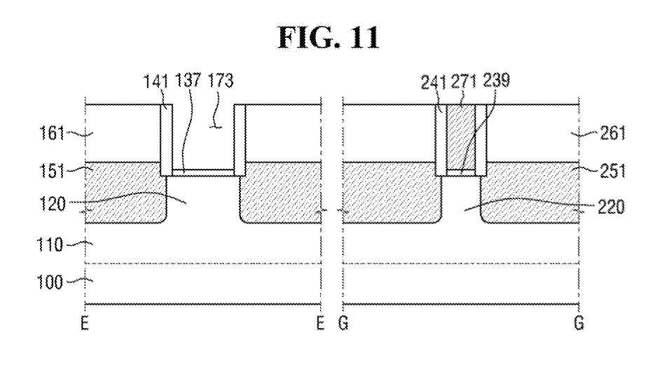

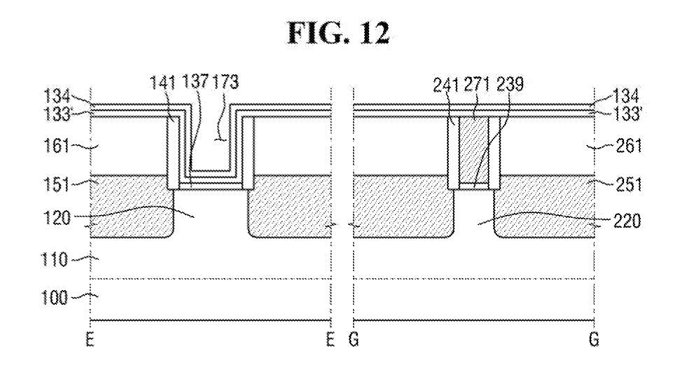

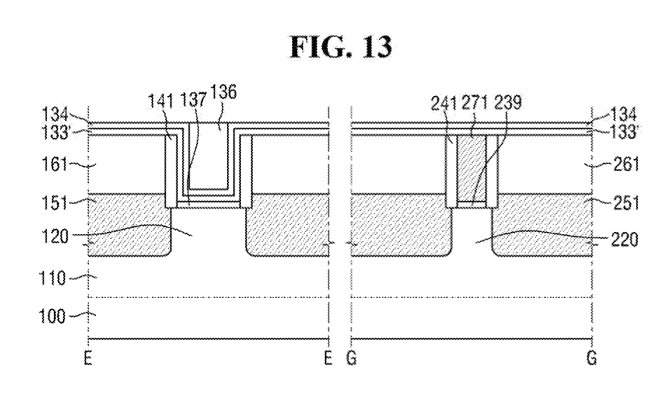

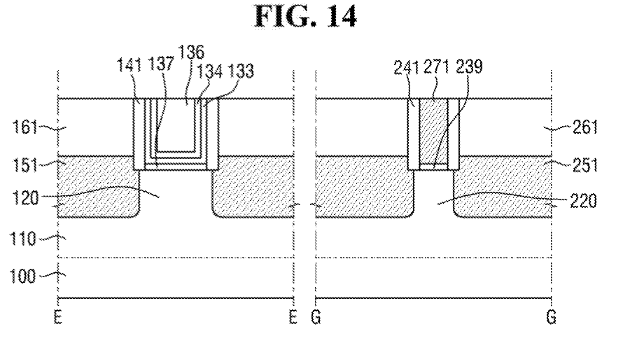

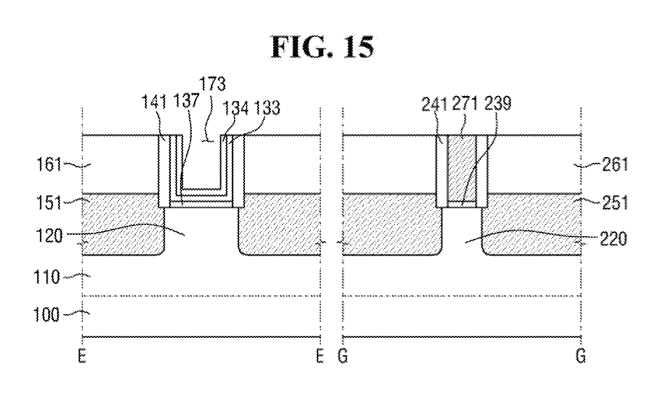

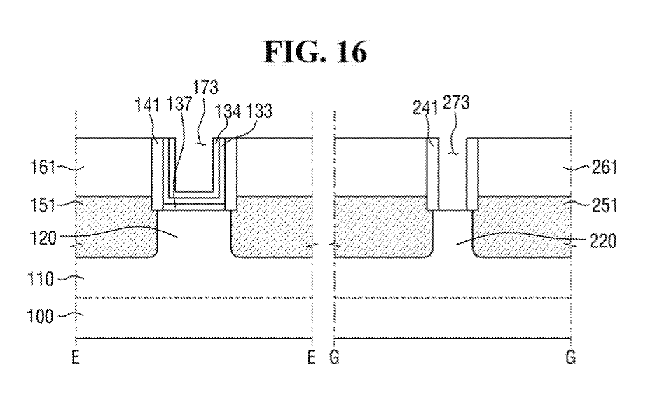

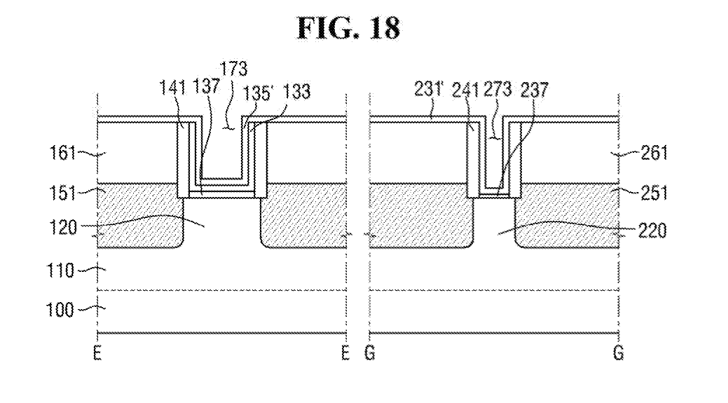

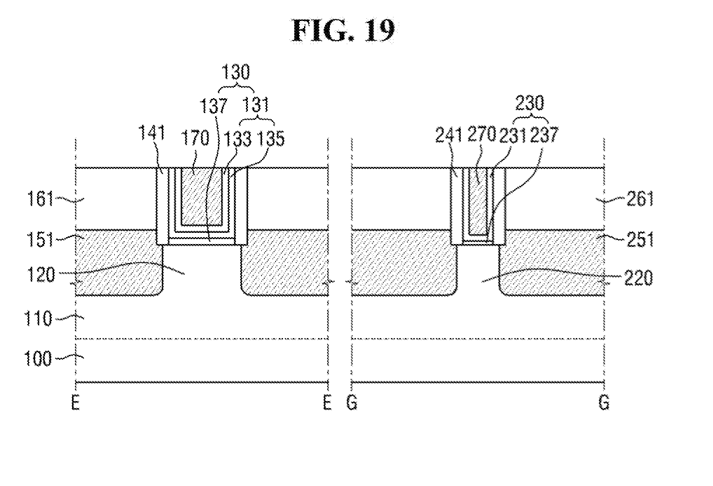

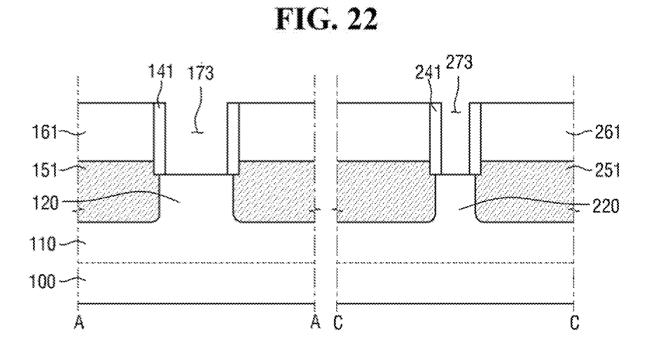

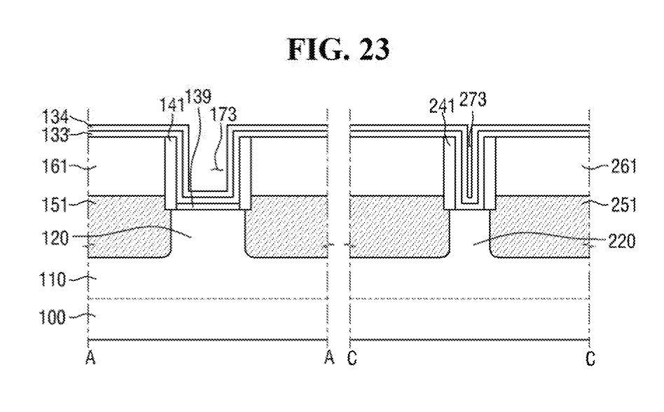

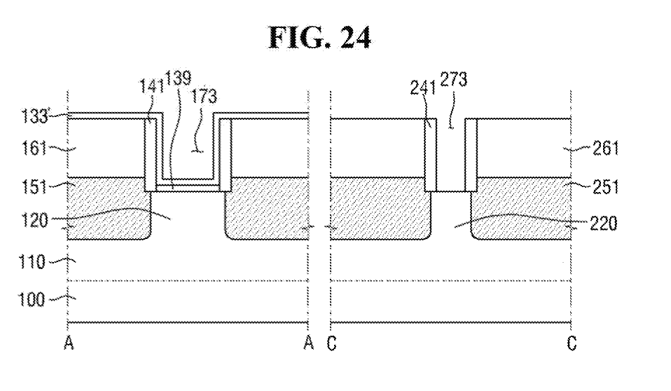

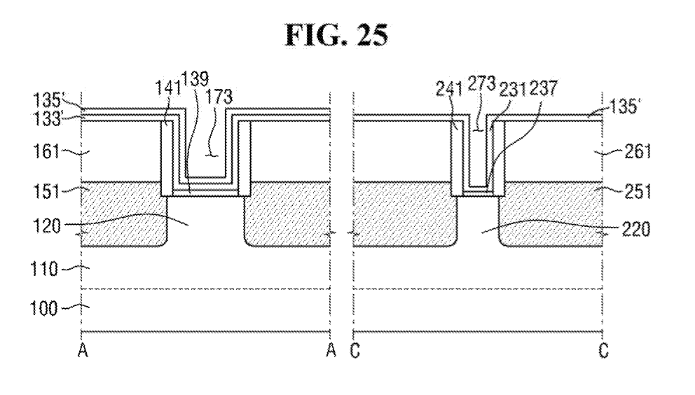

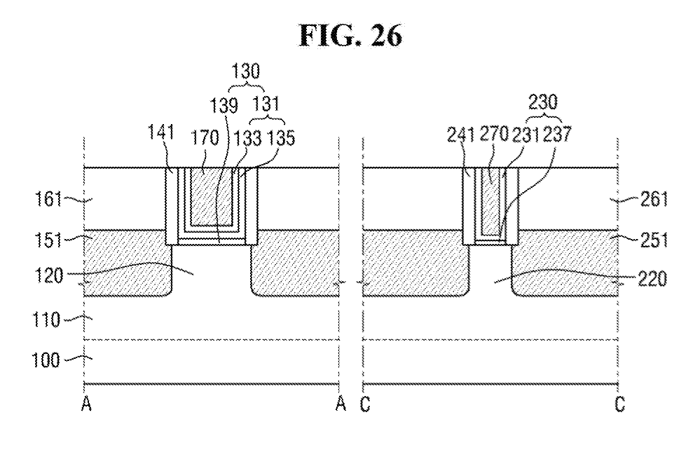

FIG. 10 to FIG. 26 are diagrams illustrating intermediate process steps of a method for fabricating a semiconductor device according to some exemplary embodiments of the present inventive concept.

FIG. 10 to FIG. 19 illustrate intermediate process steps of a method for fabricating a semiconductor device according to some exemplary embodiments of the present inventive concept. Duplicate descriptions of the same content as those of the foregoing exemplary embodiments may be omitted.

FIG. 10 to FIG. 19 are cross-sectional views taken along lines E-E and G-G of FIG. 4.

Referring to FIG. 10 to FIG. 19, a first gate oxide layer 137 and a first dummy gate electrode 171 may be sequentially stacked on the first active fin 120.

The first gate oxide layer 137 may be the interfacial layer 137 described above with reference to FIG. 4 to FIG. 9.

A second gate oxide layer 239 and a second dummy gate electrode 271 may be sequentially stacked on the second active fin 120.

The first dummy gate electrode 171 and the second dummy gate electrode 271 may include, for example, polysilicon.

The first inter layer dielectric 161 and the second inter layer dielectric 261 may cover the first dummy gate electrode 171 and the second dummy gate electrode 271, respectively, and may respectively expose an upper surface of the first dummy gate electrode 171 and an upper surface of the second dummy gate electrode 271.

The first trench 173 may be formed in the first inter layer dielectric 161 by removing the first dummy gate electrode 171.

The first dummy gate electrode 171 may be removed by a lithography process, but exemplary embodiments of the present inventive concept are not limited thereto.

The first dummy gate electrode 171 may be selectively removed by a dry etching process or a wet etching process.

The first gate oxide layer 137 may remain substantially unremoved.

An upper surface of the first gate oxide layer 137 and a sidewall of the first gate spacer 141 may be exposed by the first trench 173.

The second dummy gate electrode 271 may remain substantially unremoved.

A pre-lower high dielectric constant insulation layer 133′ may be formed along the sidewall of the first trench 173 and an upper surface of the first inter layer dielectric 161.

A hard mask layer 134 may be formed on the pre-lower high dielectric constant insulation layer 133′.

The pre-lower high dielectric constant insulation layer 133′ and the hard mask layer 134 may be formed on an upper surface of the second inter layer dielectric 261 and the upper surface of the second dummy gate electrode 271.

The hard mask layer 134 may include a metal material, such as silicon nitride (SiN), but exemplary embodiments of the present inventive concept are not limited thereto.

The hard mask layer 134 may include a material having an etch selectivity with respect to materials of the first gate spacer 141, the second gate spacer 241 and the pre-lower high dielectric constant insulation layer 133′.

A blocking pattern 136 may be formed on the hard mask layer 134. The blocking pattern 136 may substantially fill the first trench 173.

The blocking pattern 136 may be formed on the hard mask layer 134 on the first inter layer dielectric 161 and the second inter layer dielectric 261. The blocking pattern 136 may be removed by an etch-back process, which may expose the hard mask layer 134 on the first inter layer dielectric 161 and the second inter layer dielectric 261.

After forming the blocking pattern 136, the hard mask layer 134 and the pre-lower high dielectric constant insulation layer 133′ exposed by the blocking pattern 136 may be removed.

The pre-lower high dielectric constant insulation layer 133′ and the hard mask layer 134 formed on the upper surfaces of the first inter layer dielectric 161, the second inter layer dielectric 261 and the second dummy gate electrode 271 may be removed.

The pre-lower high dielectric constant insulation layer 133′ and the hard mask layer 134 may be removed by, for example, a planarizing process.

The pre-lower high dielectric constant insulation layer 133′ formed on the upper surfaces of first inter layer dielectric 161, the second inter layer dielectric 261 and the second dummy gate electrode 271 may be removed, thus forming the first lower high dielectric constant insulation layer 133 along the bottom surface and the sidewall of the first trench 173.

The blocking pattern 136 may include, for example, any one among polymer, polyimide, an organic planarizing layer (OPL) and a spin-on hardmask (SOH), but exemplary embodiments of the present inventive concept are not limited thereto.

After patterning the first lower high dielectric constant insulation layer 133, the blocking pattern 136 may be removed.

The second dummy gate electrode 271 and the second gate oxide layer 239 may be removed so as to form the second trench 273.

The second trench 273 may be formed in the second inter layer dielectric 261.

The formation of the second trench 273 may expose an upper surface of the second active fin 220 and a sidewall of the second gate spacer 241.

The hard mask layer 134 remaining on the first lower high dielectric constant insulation layer 133 may be removed.

A pre-upper high dielectric constant insulation layer 135′ may be formed along the upper surface of the first inter layer dielectric 161 and the sidewall and the bottom surface of the first trench 173.

A pre-second high dielectric constant insulation layer 231′ may be formed along the upper surface of the second inter layer dielectric 261 and the sidewall and the bottom surface of the second trench 273.

The second interfacial insulation layer 237 may be formed prior to the formation of the pre-second high dielectric constant insulation layer 231′.

The second interfacial insulation layer 237 may be formed on the bottom surface of the second trench 273.

The pre-upper high dielectric constant insulation layer 135′ and the pre-second high dielectric constant insulation layer 231′ may be formed at substantially the same level.

A first gate electrode pattern and a second gate electrode pattern may be formed on the pre-upper high dielectric constant insulation layer 135′ and the pre-second high dielectric constant insulation layer 231′. The first and second gate electrode patterns may substantially fill the first trench 173 and the second trench 273, respectively.

The first gate electrode 170 and the second gate electrode 270 may be formed by removing, through a planarization process, the first gate electrode pattern and the second gate electrode pattern formed on the pre-upper high dielectric constant insulation layer 135′ and the pre-second high dielectric constant insulation layer 231′, the pre-upper high dielectric constant insulation layer 135′ formed on the upper surface of the first inter layer dielectric 161, and the pre-second high dielectric constant insulation layer 231′ formed on the upper surface of the second inter layer dielectric 261.

The upper surfaces of the first inter layer dielectric 161 and the second inter layer dielectric 261 may be exposed through the planarization process.

The first gate electrode pattern and the second gate electrode pattern formed on the pre-upper high dielectric constant insulation layer 135′ and the pre-second high dielectric constant insulation layer 231′ may be removed to form the first upper high dielectric constant insulation layer 135 and the second high dielectric constant insulation layer 231.

The first gate electrode pattern and the second gate electrode pattern formed on the pre-upper high dielectric constant insulation layer 135′ and the pre-second high dielectric constant insulation layer 231′ may be removed to form the first gate electrode 170 and the second gate electrode 270.

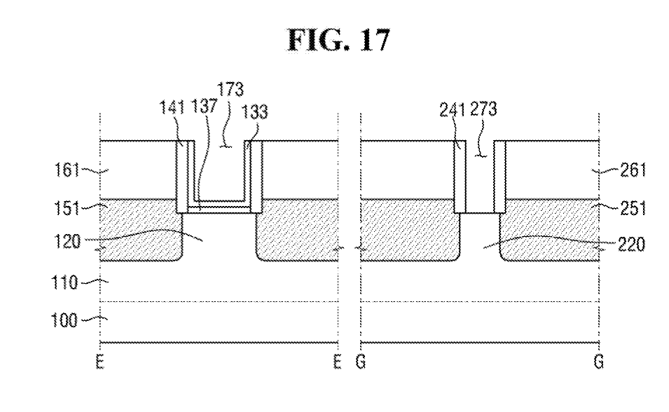

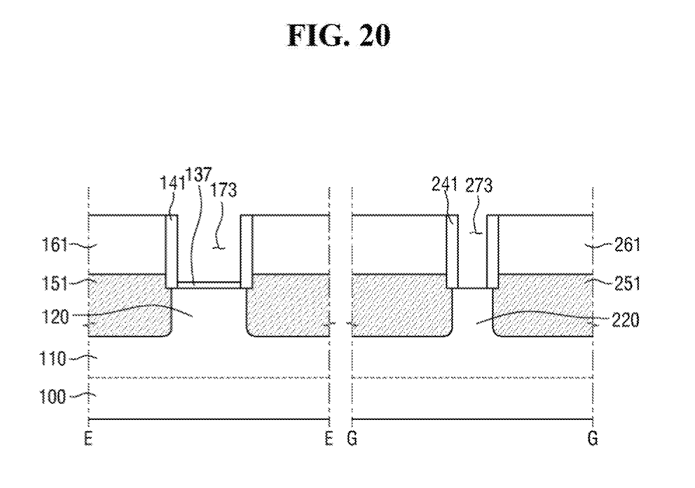

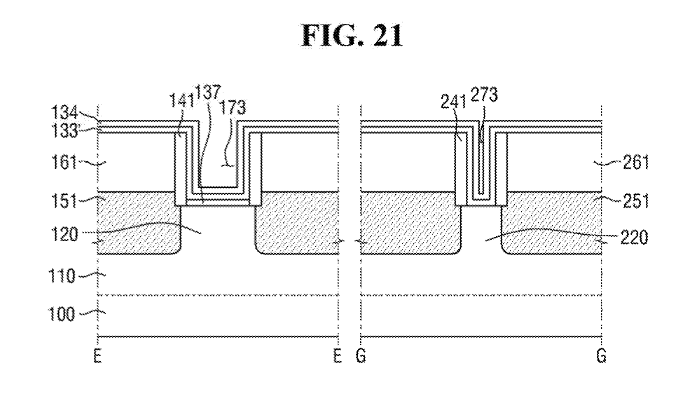

FIG. 10, FIG. 17 to FIG. 19, FIG. 20 and FIG. 21 illustrate intermediate process steps of a method for forming a semiconductor device according to some exemplary embodiments of the present inventive concept. Duplicate descriptions of the same content as those of the foregoing exemplary embodiments may be omitted.

FIG. 10, FIG. 17 to FIG. 19, FIG. 20 and FIG. 21 are cross-sectional views taken along lines E-E and G-G of FIG. 4.

Referring to FIG. 10, FIG. 17 to FIG. 19, FIG. 20 and FIG. 21, the first trench 173 and the second trench 273 may be substantially simultaneously formed.

When foaming the first trench 173, the first gate oxide layer 137 may remain unremoved.

The formation of the first trench 173 may expose the upper surface of the first gate oxide layer 137 and the sidewall of the first gate spacer 141.

When forming the second trench 273, the second gate oxide layer 239 may be selectively removed after simultaneously removing the first dummy gate electrode 171 and the second dummy gate electrode 271.

The second trench 273 may expose the upper surface of the second active fin 220 and the sidewall of the second gate spacer 241.

After forming the first trench 173 and the second trench 273, the pre-lower high dielectric constant insulation layer 133′ may be formed along the sidewall and the bottom surface of the first trench 173 and the upper surface of the first inter layer dielectric 161.

The hard mask layer 134 may be formed on the pre-lower high dielectric constant insulation layer 133′.

The pre-lower high dielectric constant insulation layer 133′ and the hard mask layer 134 may be formed along the sidewall and the bottom surface of the second trench 273 and the upper surface of the second inter layer dielectric 261.

The pre-lower high dielectric constant insulation layer 133′ and the hard mask layer 134 formed along the sidewall and the bottom surface of the second trench 273 and the upper surface of the second inter layer dielectric 261 may be selectively removed through, for example, a lithography process.

The hard mask layer 134 formed along the sidewall and the bottom surface of the first trench 173 may be removed to form the first lower high dielectric constant insulation layer 133.

FIG. 10 and FIG. 22 to FIG. 26 illustrate intermediate process steps of a method for fabricating a semiconductor device according to some exemplary embodiments of the present inventive concept. Duplicate descriptions of the same content as those of the foregoing exemplary embodiments may be omitted.

FIG. 10 and FIG. 22 to FIG. 26 are cross-sectional views taken along lines A-A and C-C of FIG. 1.

Referring to FIG. 10 and FIG. 22 to FIG. 26, the first trench 173 may be formed by removing the first dummy gate electrode 171 and the first gate oxide layer 137.

The formation of the first trench 173 may expose the upper surface of the first active fin 120 and the sidewall of the first gate spacer 141.

The second trench 273 may be formed by removing the second dummy gate electrode 271 and the second gate oxide layer 237.

After forming the first trench 173, the first interfacial insulation layer 139 may be formed on the bottom surface of the first trench 173.

After forming the first interfacial insulation layer 139, the pre-lower high dielectric constant insulation layer 133′ may be formed on the sidewall of the first trench 173, an upper surface of the first interfacial insulation layer 139 and the upper surface of the first inter layer dielectric 161.

The hard mask layer 134 may be formed on the pre-lower high dielectric constant insulation layer 133′.

According to some exemplary embodiments of the present inventive concept, the first gate insulation layer 130 may include the first interfacial insulation layer 139. The first gate insulation layer 130 might not include the first gate oxide layer 137.

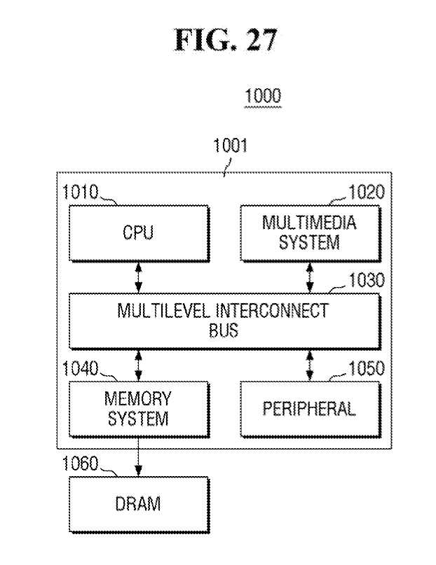

FIG. 27 is a block diagram of an SoC system including a semiconductor device according to some exemplary embodiments of the present inventive concept.

Referring to FIG. 27, an SoC system 1000 may include an application processor 1001 and a DRAM 1060.

The application processor 1001 may include a central processing unit 1010, a multimedia system 1020, a multilevel interconnect bus 1030, a memory system 1040 and a peripheral circuit 1050.

The central processing unit 1010 may perform arithmetic operation for driving the SoC system 1000. In some exemplary embodiments of the present inventive concept, the central processing unit 1010 may be configured to have a multi-core environment including a plurality of cores.

The multimedia system 1020 may perform various multimedia functions in the SoC system 1000. The multimedia system 1020 may include a 3D engine module, a video codec, a display system, a camera system, and a post processor.

The multilevel interconnect bus 1030 may be used to enable data communication among the central processing unit 1010, the multimedia system 1020, the memory system 1040 and the peripheral circuit 1050. In some exemplary embodiments of the present inventive concept, the multilevel interconnect bus 1030 may have a multi-layer structure. For example, the multilevel interconnect bus 1030 may include a multi-layer advanced high-performance bus (AHB) and a multi-layer advanced extensible interface (AXI), but exemplary embodiments of the present inventive concept are not limited thereto.

The memory system 1040 may connect the application processor 1001 to an external memory (for example, the DRAM 1060) and may operate at relatively high speed. In some exemplary embodiments of the present inventive concept, the memory system 1040 may include a separate controller (for example, a DRAM controller) controlling the external memory (for example, the DRAM 1060).

The peripheral circuit 1050 may connect the SoC system 1000 to an external device (for example, a main board). Thus, the peripheral circuit 1050 may have various interfaces for compatibility with the external device connected to the SoC system 1000.

The DRAM 1060 may function as an operation memory for operating the application processor 1001. In some exemplary embodiments of the present inventive concept, the DRAM 1060 may be disposed outside the application processor 1001. For example, the DRAM 1060 may be packaged with the application processor 1001 into a package on package.

While the present inventive concept has been particularly shown and described with reference to exemplary embodiments thereof, it will be understood by those of ordinary skill in the art that various changes in form and detail may be made therein without departing from the spirit and scope of the present inventive concept.

1. A semiconductor device comprising:
a first active fin and a second active fin disposed on a substrate;
a first gate electrode intersecting the first active fin;
a second gate electrode intersecting the second active fin;
a first gate insulation layer comprising a first high dielectric constant insulation layer, wherein the first high dielectric constant insulation layer comprises a first lower high dielectric constant insulation layer and a first upper high dielectric constant insulation layer sequentially disposed on the first active fin, and wherein the first gate insulation layer is disposed between the first gate electrode and the first active fin; and
a second gate insulation layer comprising a second high dielectric constant insulation layer, wherein the second high dielectric constant insulation layer comprises a second lower high dielectric constant insulation layer and a second upper high dielectric constant insulation layer sequentially disposed on the second active fin, and wherein the second gate insulation layer is disposed between the second gate electrode and the second active fin.

2. (canceled)

3. The semiconductor device of claim 1, wherein the second high dielectric constant insulation layer comprises a same material as a material included in the first high dielectric constant insulation layer.

4. The semiconductor device of claim 1, wherein the first gate insulation layer comprises a first interfacial insulation layer between the first active fin and the first high dielectric constant insulation layer, and wherein the second gate insulation layer comprises a second interfacial insulation layer between the second active fin and the second high dielectric constant insulation layer.

5. The semiconductor device of claim 4, wherein a thickness of the first interfacial insulation layer and a thickness of the second interfacial insulation layer are different from each other.

6. The semiconductor device of claim 4, wherein a dielectric constant of the first high dielectric constant insulation layer is higher than a dielectric constant of the first interfacial insulation layer, and wherein a dielectric constant of the second high dielectric constant insulation layer is higher than a dielectric constant of the second interfacial insulation layer.

7. The semiconductor device of claim 1, wherein the first high dielectric constant insulation layer is disposed on a bottom surface of the first gate electrode and a sidewall of the first gate electrode, and wherein the second high dielectric constant insulation layer is disposed on a bottom surface of the second gate electrode and a sidewall of the second gate electrode.

8. The semiconductor device of claim 1, wherein the thickness of the first high dielectric constant insulation layer between a bottom surface of the first gate electrode and an upper surface of the first active fin is thicker than the thickness of the second high dielectric constant insulation layer between a bottom surface of the second gate electrode and an upper surface of the second active fin.

9. The semiconductor device of claim 1, wherein a width of the first gate electrode is different from a width of the second gate electrode.

10. A semiconductor device comprising:
a first active fin and a second active fin disposed on a substrate;
a first gate electrode intersecting the first active fin;
at least two first gate spacers disposed on opposite sidewalls of the first gate electrode, wherein the first gate spacers define a first trench;
a first gate insulation layer comprising a first high dielectric constant insulation layer between the first gate electrode and the first active fin, wherein the first gate insulation layer is disposed on a sidewall and a bottom surface of the first trench, and wherein the first high dielectric constant insulation layer comprises a first lower high dielectric constant insulation layer and a first upper high dielectric constant insulation layer;
a second gate electrode intersecting the second active fin;
at least two second gate spacers disposed on opposite sidewalls of the second gate electrode, wherein the second gate spacers define a second trench having a width narrower than a width of the first trench; and
a second gate insulation layer comprising a second high dielectric constant insulation layer between the second gate electrode and the second active fin, wherein the second high dielectric constant insulation layer comprises a second lower high dielectric constant insulation layer and a second upper high dielectric constant insulation layer sequentially disposed on the second active fin, wherein the second gate insulation layer is disposed along a sidewall and a bottom surface of the second trench, and wherein a thickness of the first high dielectric constant insulation layer is thicker than a thickness of the second high dielectric constant insulation layer.

11. (canceled)

12. The semiconductor device of claim 10, wherein the thickness of the first high dielectric constant insulation layer between a bottom surface of the first gate electrode and an upper surface of the first active fin is thicker than the thickness of the second high dielectric constant insulation layer between a bottom surface of the second gate electrode and an upper surface of the second active fin.

13. The semiconductor device of claim 10, wherein the first gate insulation layer comprises a first interfacial insulation layer between the first active fin and the first high dielectric constant insulation layer, and wherein the second gate insulation layer comprises a second interfacial insulation layer between the second active fin and the second high dielectric constant insulation layer.

14. The semiconductor device of claim 13, wherein a dielectric constant of the first high dielectric constant insulation layer is higher than a dielectric constant of the first interfacial insulation layer, and wherein a dielectric constant of the second high dielectric constant insulation layer is higher than a dielectric constant of the second interfacial insulation layer.

15. The semiconductor device of claim 13, wherein the first interfacial insulation layer and the second interfacial insulation layer comprise silicon oxide.

16. A semiconductor device comprising:
a substrate;
a first active fin disposed on the substrate;
a first gate insulation layer disposed on the first active fin, wherein the first gate insulation layer includes a first high dielectric constant insulation layer including a first upper high dielectric constant insulation layer and a first lower high dielectric constant insulation layer;
a first gate electrode disposed on the first gate insulation layer;
a second active fin disposed on the substrate; and
a second gate insulation layer disposed on the second active fin, wherein the second gate insulation layer includes a second high dielectric constant insulation layer, wherein the second high dielectric constant insulation layer comprises a second lower high dielectric constant insulation layer and a second upper high dielectric constant insulation layer sequentially disposed on the second active fin.

17. The semiconductor device of claim 16, wherein the first gate insulation layer includes a first interfacial layer, wherein a width of the first interfacial layer is wider than a width of the first gate electrode, wherein the second gate insulation layer includes a second interfacial layer, and wherein a width of the second interfacial layer is wider than a width of the second gate electrode.

18. The semiconductor device of claim 16, wherein a thickness of the first high dielectric constant insulation layer is greater than a thickness of the second high dielectric constant insulation layer.

19. The semiconductor device of claim 16, further comprising a first spacer disposed on a sidewall of the first gate electrode and a second spacer disposed on a sidewall of the second gate electrode.

20. The semiconductor device of claim 17, wherein an upper surface of the first interfacial layer is in contact with the first high dielectric constant insulation layer, wherein a lower surface of the first interfacial layer is in contact with the first active fin, wherein an upper surface of the second interfacial layer is in contact with the second high dielectric constant insulation layer, and wherein a lower surface of the second interfacial layer is in contact with the second active fin.

21. The semiconductor device of claim 1, wherein a thickness of the first high dielectric constant insulation layer is thicker than a thickness of the second high dielectric constant insulation layer.

22. The semiconductor device of claim 1, wherein the second lower high dielectric constant insulation layer comprises a same material as a material included in the second upper high dielectric constant insulation layer.
